(19) United States
(12) Patent Application Publication
(10) Pub. No.: US 2008/0026555 A1
(43) Pub. Date: Jan. 31, 2008

(54) Sacrificial tapered trench opening for damascene interconnects

(76) Inventors: Valery M. Dubin, Portland, OR (US); Rohan N. Akolkar, Hillsboro, OR (US); Scott B. Clendenning, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/494,389

(22) Filed: Jul. 26, 2006

(51) Int. Cl. H01L 21/44

(52) U.S. Cl. 438/597

(57) ABSTRACT

A method for forming a trench with a flared opening in a dielectric layer comprises providing a semiconductor substrate having a dielectric layer deposited thereon, depositing and patterning a photoresist layer atop the dielectric layer to form at least two photoresist structures, applying a plasma etch to define a flared trench profile in the photoresist structures, and applying a dry etch chemistry to etch a trench in the dielectric layer using the photoresist structures as a mask, wherein the flared trench profile is transferred from the photoresist structures to the dielectric layer. The dry etch chemistry may comprise an anisotropic plasma etch.

### BACKGROUND

In the manufacture of integrated circuits, copper interconnects are generally formed on a semiconductor substrate using a copper dual damascene process. Such a process begins with a trench being etched into a dielectric layer and filled with a barrier layer, an adhesion layer, and a seed layer. A sputtering process may be used to deposit a tantalum nitride (TaN) barrier layer and a tantalum (Ta) or ruthenium (Ru) adhesion layer (i.e., a TaN/Ta or TaN/Ru stack) into the trench. The TaN barrier layer prevents copper from diffusing into the underlying dielectric layer. The Ta/Ru adhesion layer enables subsequently deposited metals to nucleate on the TaN barrier layer. This may be followed by a sputtering process to deposit a copper seed layer into the trench and an electroplating process to fill the trench with bulk copper metal.

As device dimensions scale down, the trench becomes more narrow, thereby causing the aspect ratio of the trench to become more aggressive. This gives rise to issues such as trench overhang during the copper deposition processes. Trench overhang eventually causes the trench opening to become pinched-off, resulting in inadequate gapfill and void formation. Accordingly, improved interconnect fabrication processes are needed to overcome issues such as trench overhang, inadequate gapfill, and voids as device dimensions continue to scale down.

### BRIEF DESCRIPTION OF THE DRAWINGS

FIGS. 1A to 1E illustrate a conventional damascene process for fabricating copper interconnects.

FIG. 2 illustrates a trench having a flared trench opening that may be used to form a metal interconnect.

FIG. 3 is a method of forming a trench with a flared opening in accordance with one implementation of the invention.

FIGS. 4A to 4I illustrate structures that are formed while carrying out the method of FIG. 3.

FIG. 5 is a method of forming a trench with a flared opening in accordance with another implementation of the invention.

FIGS. 6A to 6G illustrate structures that are formed while carrying out the method of FIG. 5.

### DETAILED DESCRIPTION

Described herein are systems and methods of fabricating dual damascene interconnects using a flared trench opening. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

Implementations of the invention enable substantially void-free copper interconnects to be formed at the sub-50 nanometer (nm) level with aspect ratios greater than 5:1. This is achieved using an interconnect fabrication process that implements a dual damascene technique having flared trench openings. The flared trench openings substantially reduce or eliminate trench overhang, thereby allowing the trench to be filled in a substantially void-free manner. This is due in part to the flared trench openings providing a larger opening for the copper metal to enter during the electroplating deposition process. The use of flared trench openings also provides robust trench sidewall seed coverage.

In some implementations of the invention, the flared trench openings may be fabricated by applying a plasma treatment during the photolithography process to form a flared photoresist profile. The flared photoresist profile may then be transferred to an underlying interlayer dielectric (ILD) during an etching process. In another implementation of the invention, the flared trench openings may be fabricated by depositing a fluorine-based material atop a patterned photoresist layer to create a flared profile that can also be transferred to the underlying ILD.

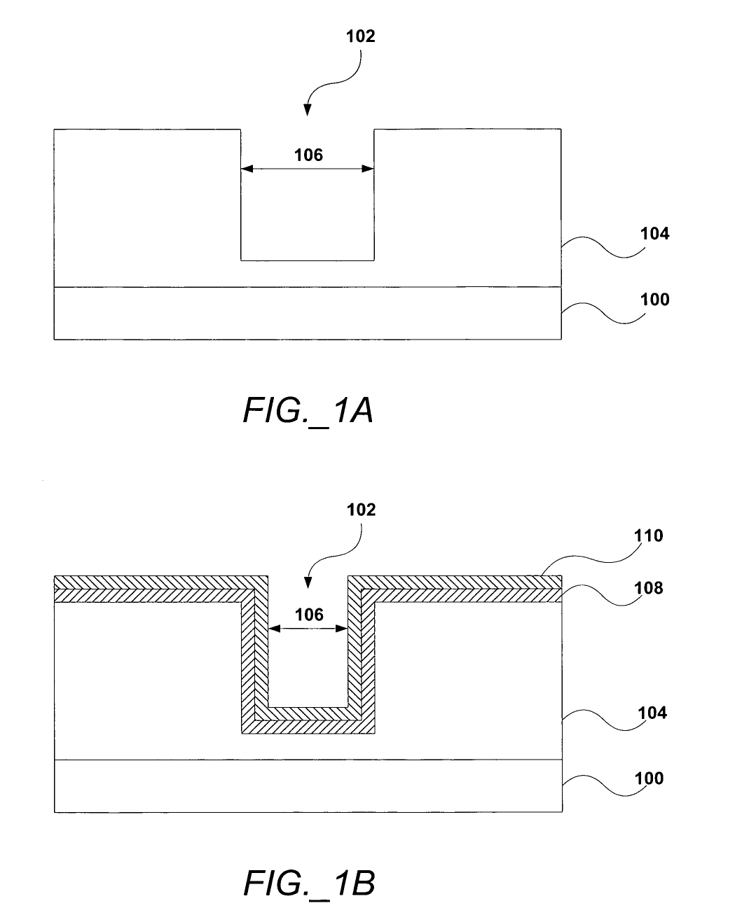

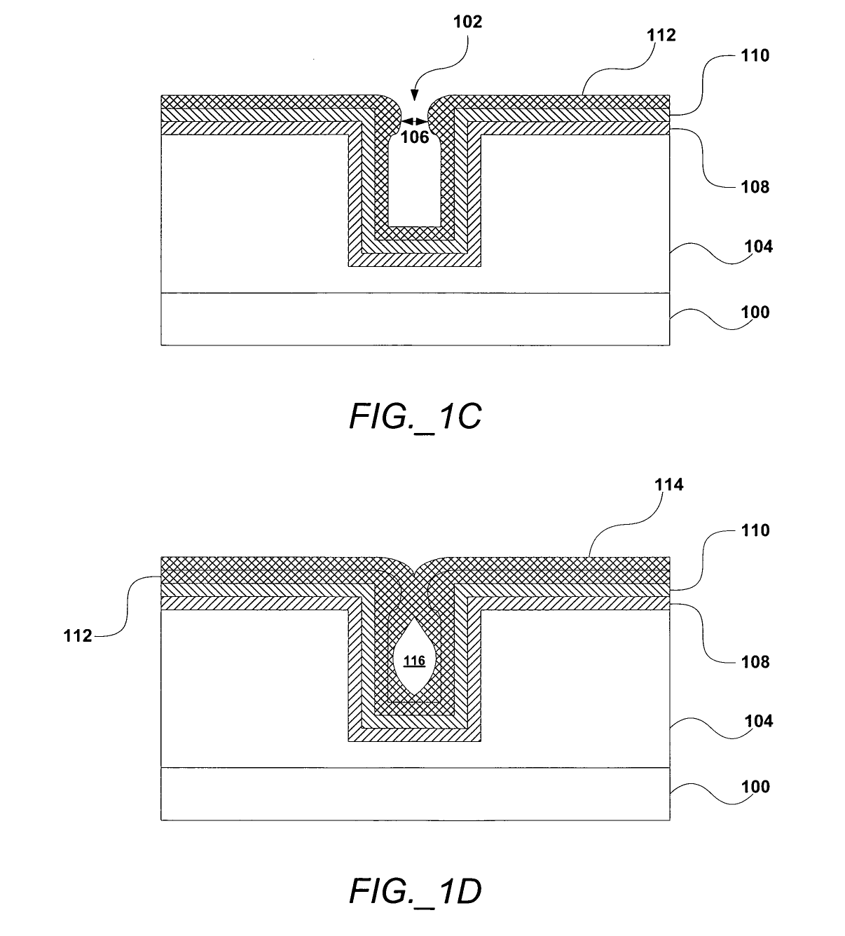

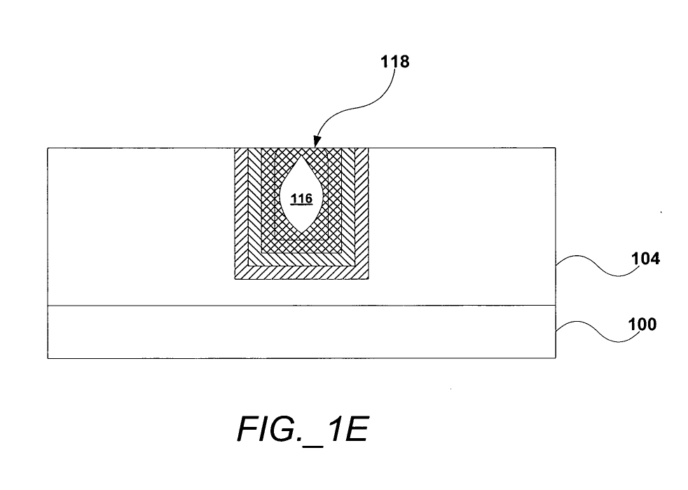

For reference, FIGS. 1A to 1E illustrate a conventional damascene process for fabricating copper interconnects on a semiconductor wafer. FIG. 1A illustrates a substrate 100, such as a semiconductor wafer, that includes a trench 102 that has been etched into a dielectric layer 104. The trench 102 includes a gap 106 through which metal may enter during metallization processes.

FIG. 1B illustrates the trench 102 after a conventional barrier layer 108 and a conventional adhesion layer 110 have been deposited. The barrier layer 108 prevents copper metal from diffusing into the dielectric layer 104. The adhesion layer 110 enables copper metal to become deposited onto the barrier layer 108. The barrier layer 108 is generally formed using a material such as tantalum nitride (TaN) and is deposited using a physical vapor deposition (PVD) process such as a sputtering process. The barrier layer 108 may be around 0.5 Angstroms (Å) to 10 nanometers (nm) thick, although it is generally around 5 nm thick. The adhesion layer 110 is generally formed using a metal such as tantalum (Ta) or ruthenium (Ru) and is also deposited using a PVD process. The adhesion layer 110 is generally around 2 nm to 10 nm thick.

After the adhesion layer 110 is formed, the conventional damascene process of FIG. 1 uses two independent deposition processes to fill the trench 102 with copper metal. The first deposition process is a PVD process that forms a non-conformal copper seed layer. The second deposition process is a plating process, such as an electroplating (EP) process or an electroless plating (EL) process, that deposits a bulk copper layer to fill the trench 102.

FIG. 1C illustrates the trench 102 after a conventional copper seed layer 112 has been deposited onto the adhesion layer 110 using a PVD process. The copper seed layer 112 enables or catalyzes a subsequent plating process to fill the interconnect with copper metal. As shown, trench overhang begins to occur during the PVD of the copper seed layer 112. In many instances, the copper seed deposition completely pinches off the trench opening, leaving a substantial void in the trench 102 and preventing any further metal from entering.

FIG. 1D illustrates the trench 102 after an copper electroplating deposition process has been carried out. If the PVD of the copper seed layer 112 has not closed off the trench, copper metal 114 enters the trench through the gap 106 where, due to the narrow width of the gap 106, issues such as trench overhang and pinching off of the trench opening may occur that lead to defects. For instance, as shown in FIG. 1D, trench overhang may occur that pinches off the opening of the trench 102, creating a void 116 that will appear in the final interconnect structure.

FIG. 1E illustrates the trench 102 after a chemical mechanical polishing (CMP) process is used to planarize the deposited copper metal 114. The CMP results in the formation of a metal interconnect 118. As shown, the metal interconnect 118 includes the void 116 that was formed when the available gap 106 was too narrow and the resulting trench overhang pinched off the trench opening. Furthermore, a substantial portion of the metal interconnect 118 comprises Ta and/or Ru from the adhesion layer 110 and the barrier layer 108.

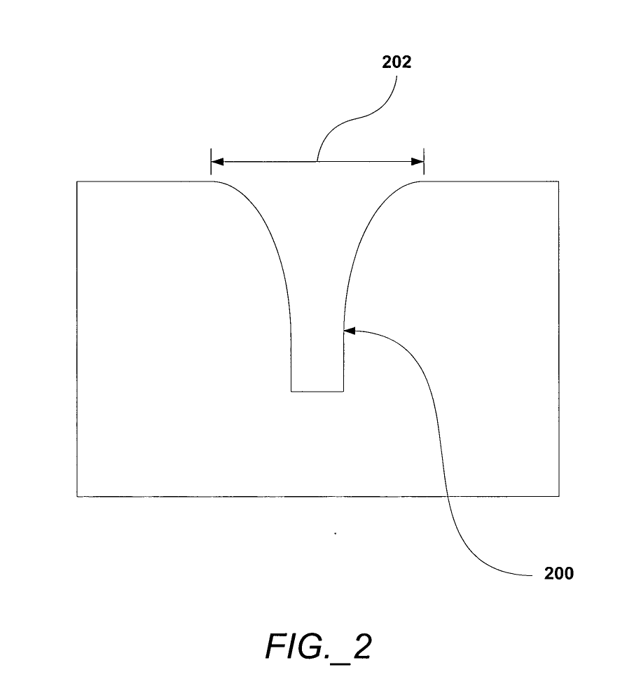

FIG. 2 illustrates a trench 200 having a flared trench opening as described herein. As shown, the trench 200 includes a trench opening 202 that flares outward, thereby increasing the size of the trench opening 202. In implementations of the invention, the aspect ratio of such a trench 200 having a flared trench opening 202 may be around 2:1 or greater, despite the fact that the trench 202 is relatively deep. A substantial portion of the trench 202 actually has an aggressive aspect ratio, but due to the flaring of the trench opening 202, the overall aspect ratio of the trench 200 remains low.

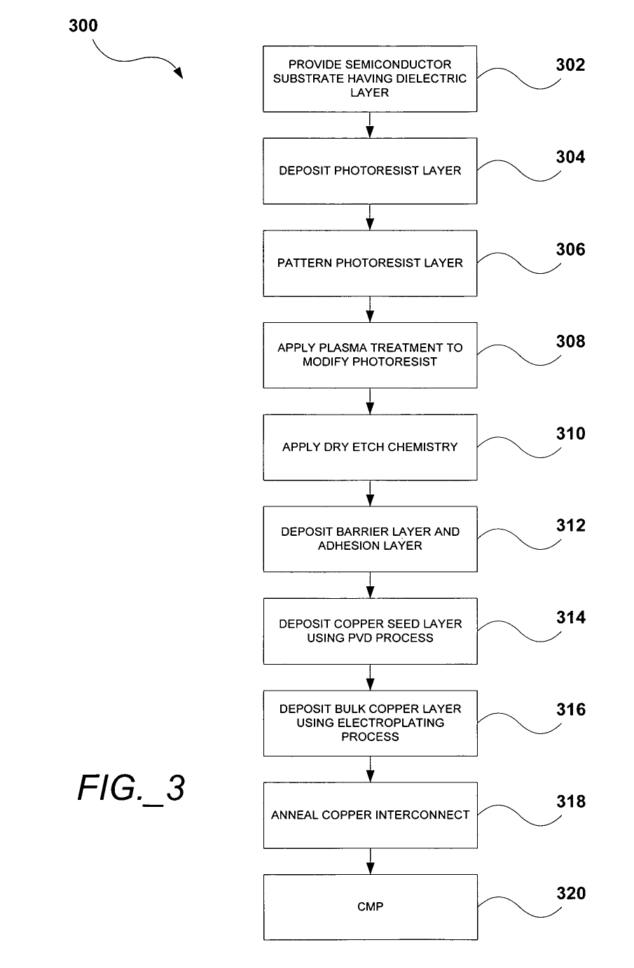

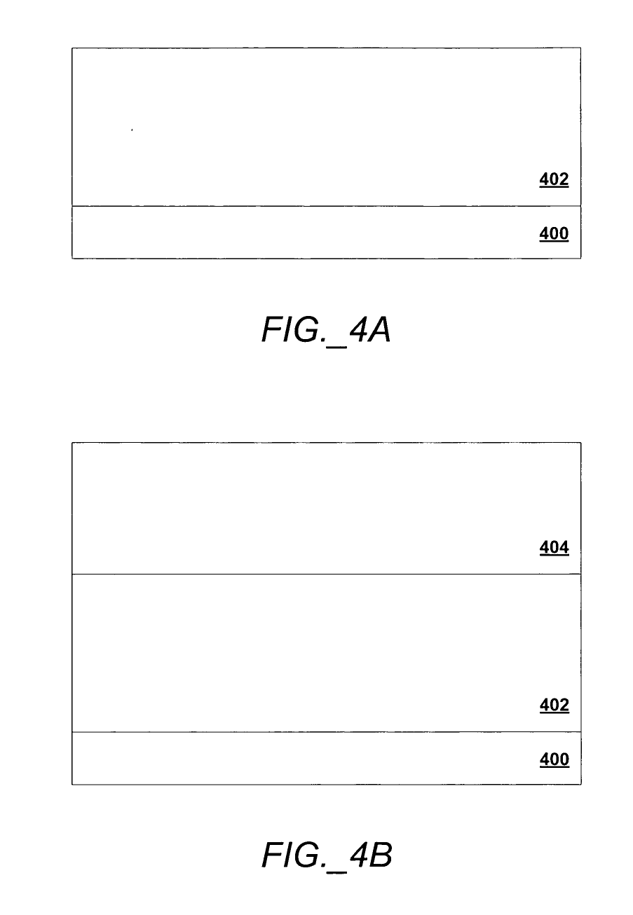

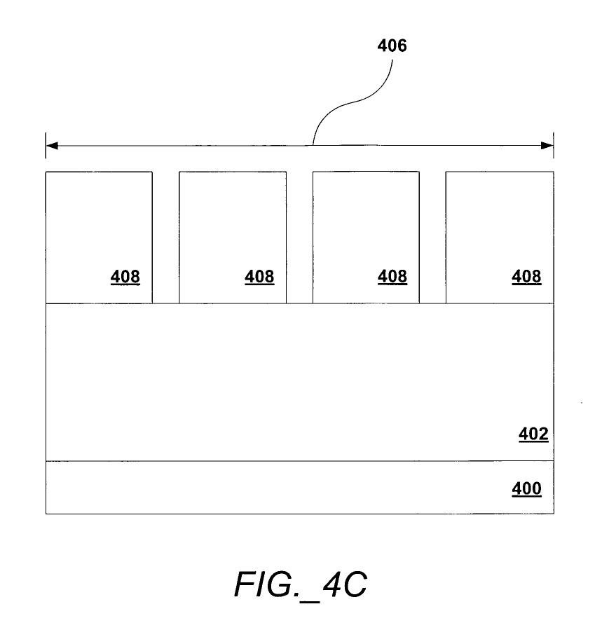

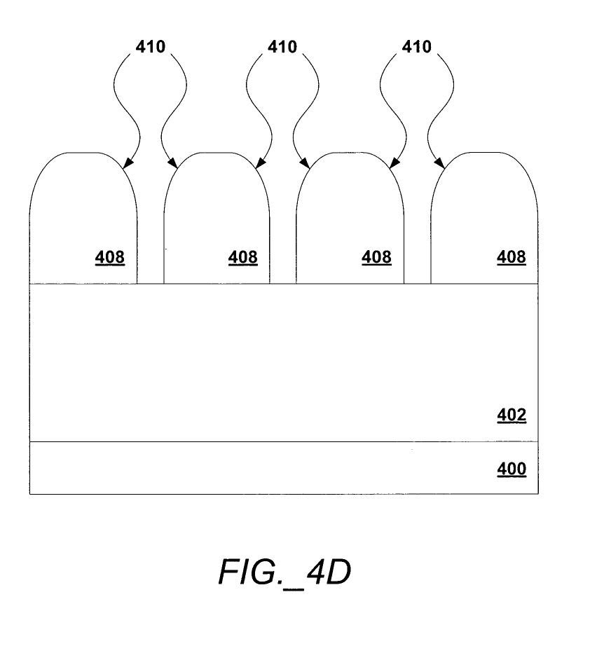

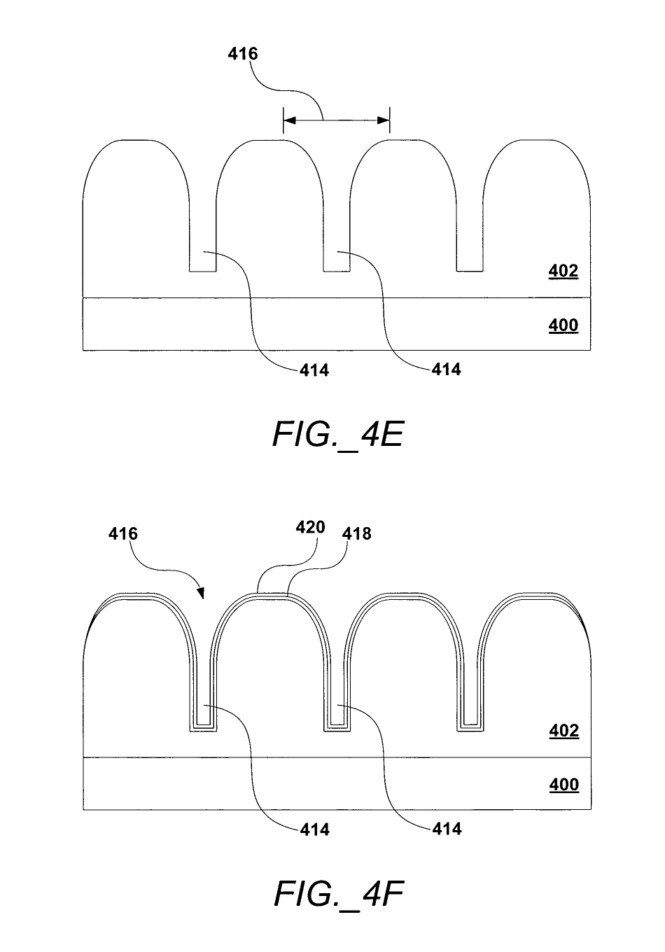

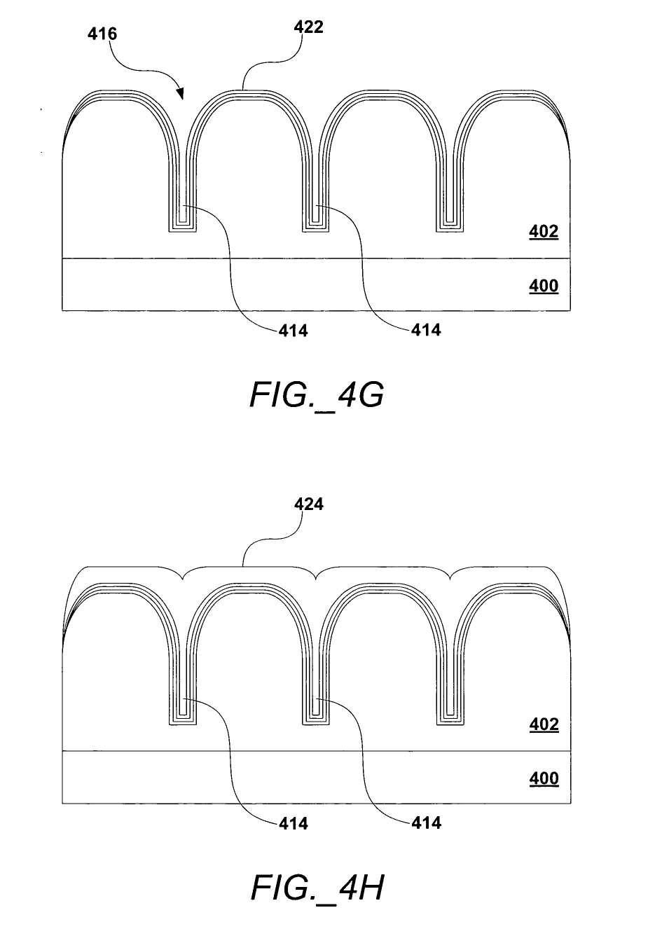

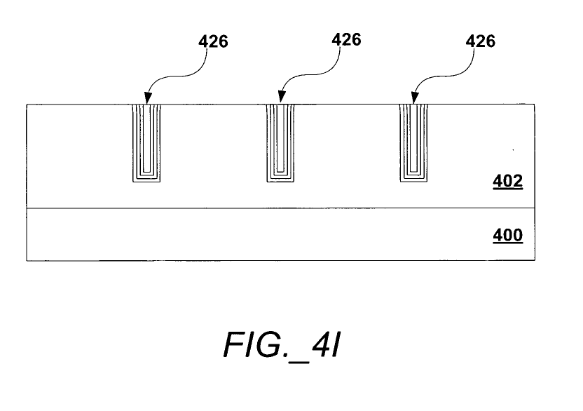

FIG. 3 is a damascene fabrication process 300 for forming a copper interconnect using a flared trench opening in accordance with one implementation of the invention. FIGS. 4A to 4I illustrate structures that are formed when carrying out the fabrication process 300. To aid in understanding this implementation, the FIGS. 4A to 4I will be referenced during the discussion of the fabrication process 300.

First, a semiconductor substrate is provided that includes a dielectric layer (process 302 of FIG. 3). The semiconductor substrate may be formed using a bulk silicon or a silicon-on-insulator substructure. In other implementations, the substrate may be formed using alternate materials, which may or may not be combined with silicon, that include but are not limited to germanium, indium antimonide, lead telluride, indium arsenide, indium phosphide, gallium arsenide, or gallium antimonide. Although a few examples of materials from which the substrate may be formed are described here, any material that may serve as a foundation upon which a semiconductor device may be built falls within the spirit and scope of the present invention. Active devices may be formed on the semiconductor substrate, including but not limited to transistors, such as conventional complementary metal-oxide-semiconductor (CMOS) transistors. Other structures such as contacts, isolation structures, and capacitors may be formed on the semiconductor substrate as well.

The dielectric layer provides insulation between electrical components. As semiconductor device dimensions decrease, electrical components such as interconnects must be formed closer together. This increases the capacitance between components with the resulting interference and crosstalk degrading device performance. To reduce the interference and crosstalk, dielectric materials with lower dielectric constants (i.e., low-k dielectric materials) are used to provide insulation between electrical components. Common dielectric materials that may be used in the dielectric layer include, but are not limited to, oxides such as silicon dioxide (SiO₂) and carbon doped oxide (CDO), organic polymers such as perfluorocyclobutane (PFCB), or fluorosilicate glass (FSG).

FIG. 4A illustrates a semiconductor substrate 400 having a dielectric layer 402 deposited thereon. Although not shown in FIG. 4A, the dielectric layer 402 may include one or more vias that are formed using conventional photolithography patterning processes. The formation of vias may be part of a dual damascene process into which the fabrication process 300 may be integrated.

Next, a layer of photoresist material is deposited atop the dielectric layer (process 304). In some implementations, a spin-on deposition (SOD) process may be used to deposit the photoresist material. Many conventional photoresist materials may be used in implementations of the invention, as are well known by those of skill in the art. FIG. 4B illustrates a photoresist layer 404 that has been deposited upon the dielectric layer 402.

The layer of photoresist material is then patterned using conventional photolithography techniques to form a photoresist mask (process 306). As is well known in the art, the deposited photoresist layer may be patterned by exposing the photoresist material to ultraviolet radiation through a patterned optical mask, baking or hardening the photoresist material, and developing the photoresist material. The pattern in the optical mask is transferred to the photoresist material during the exposure step. Portions of the photoresist material are removed during the development step. The photoresist structures that remain after development function as a mask that defines a trench profile that can be transferred into the underlying dielectric layer using an etching process.

FIG. 4C illustrates the photoresist layer 404 after it has undergone the patterning process described above, resulting in a photoresist mask 406. The photoresist mask 406 is composed of a plurality of individual photoresist structures 408 that shield portions of the dielectric layer 402. The photoresist structures 408 may vary in size and configuration. Between the individual photoresist structures 408 are exposed portions of the dielectric layer 402 that are vulnerable to an etching process. As shown, the top edges 410 of each photoresist structure 408 are squared off.

A plasma is then applied to the photoresist mask to round off the top edges of the photoresist structures, thereby modifying the trench profile to define trenches with outwardly flared trench openings (process 308). In some implementations, the plasma species used may include, but is not limited to, argon (Ar), forming gas (e.g., 5% H₂ in N₂), phosphorous (P), nitrogen (N), carbon (C), or boron (B). The plasma introduces an energetic species that tends to etch portions of the photoresist material to round off the previously square edges at the top of each photoresist structure. The process parameters may be adjusted to induce the desired modification to the photoresist material, such as increasing or decreasing the degree to which the trench openings flare outward. These process parameters include, but are not limited to, the plasma pulse duration, the plasma power modulation, the entering plasma gases, reactor pressure, and temperature. For instance, in some implementations, an RF energy source may be applied at a power that ranges from 300 Watts (W) to 1200 W and at a frequency of 13.56 MHz, 27 Mhz, or 60 MHz. The reactor pressure may range from around 150 mTorr to around 500 mTorr.

FIG. 4D illustrates the photoresist structures 408 after being exposed to a plasma treatment. As shown, the top edges 410 of each photoresist structure 408 have been etched away to form rounded edges 412. These rounded edges 412 create a flared trench profile in the photoresist mask 406 that can be transferred to the underlying dielectric layer 402 during a subsequent etching process.

Next, a dry etch chemistry is applied to the photoresist mask and the portions of the dielectric layer left exposed by the photoresist mask (process 310). As will be appreciated by those of skill in the art, conventional dry etch chemistries for etching the photoresist mask and the dielectric materials may be used here. In some implementations of the invention, the dry etch chemistry may consist of a plasma etch.

In accordance with implementations of the invention, the plasma etch of the dielectric layer is configured so as to transfer the flared trench profile of the photoresist mask into the dielectric layer. This is accomplished by choosing plasma conditions such that the direction of the ion bombardment and resulting physical sputtering of the dielectric is determined by collisions with the sidewalls in the flared trench profile of the overlying photoresist mask. In this case, rather than only impinging on the underlying exposed dielectric layer with an orthogonal trajectory, as is the ideal case with vertical sidewalls in the photoresist, incoming ions are scattered off the flared surface of the photoresist mask causing them to hit the dielectric layer at different angles. Ion scattering off the flared photoresist surface leads to the transfer of the flared trench profile into the underlying dielectric layer. The trenches formed in the dielectric layer therefore have flared trench openings.

In implementations of the invention, the plasma etch may utilize gases such as CF₄, CF₃H, CF₂H₂, C₄F₈, C₄F₆, O₂, Ar, He, Xe, N₂, and CO. Process parameters for some implementations of the plasma etch may include gas flows between 2 sccm and 1000 sccm, pressures between 20 mTorr and 100 mTorr, and an RF energy between 500 W and 4500 W that may be applied at various combinations of frequencies (e.g., 2, 13.56, 27 and 60 MHz) to the top and/or bottom electrodes. Process parameters other than these may be used in alternate implementations. Following the plasma etch, the wafer may be cleaned either by a plasma ashing process or a wet chemistry clean, as is known in the art, to remove any remaining photoresist.

FIG. 4E illustrates trenches 414 that have been etched into the dielectric layer 402 using the photoresist mask 406. The trenches 414 have flared trench openings 416, similar to the flared trench profile that was defined in the photoresist mask 406.

Once the trenches have been formed with flared trench openings, metal may be deposited to form the interconnect structure. First, a barrier layer and an adhesion layer are deposited into the trenches (process 312). The barrier layer prevents copper in the interconnect from diffusing into the dielectric layer while the adhesion layer enables copper metal to adhere to the barrier layer. Both layers are generally deposited using a PVD process, such as a sputtering process. The barrier layer is generally formed using a material such as tantalum nitride (TaN) and may be around 0.5 Angstroms (Å) to 10 nanometers (nm) thick, although it is generally around 5 nm thick. The adhesion layer is generally formed using a metal such as tantalum (Ta) or ruthenium (Ru) and is generally around 2 nm to 10 nm thick. Alternate metals that may be used in the barrier layer and/or the adhesion layer include, but are not limited to, tungsten nitride (WN), titanium nitride (TiN), titanium (Ti), tungsten (W), molybdenum (Mo), molybdenum nitride (MoN), niobium (Nb), niobium nitride (NbN), and iridium (Ir).

FIG. 4F illustrates the trenches 414 after a conventional barrier layer 418 and a conventional adhesion layer 420 have been deposited. As shown, the flared trench openings 416 remain wide open for the subsequent copper deposition.

After the barrier and adhesion layers are formed, two separate deposition processes are used to fill the trench with copper metal. The first deposition process is a PVD process that forms a non-conformal copper seed layer (process 314). The flared trench openings prevent trench overhang from occurring during the copper seed layer deposition, therefore, the copper seed layer does not pinch off the trenches. The flared trench openings allow PVD process to deposit the copper seed layer in a robust manner with good sidewall coverage. Metals that may be used as a copper seed layer include, but are not limited to, copper, cobalt, nickel, silver, gold, and Ru.

FIG. 4G illustrates the trenches 414 after a conventional copper seed layer 422 has been deposited onto the adhesion layer 420 using a PVD process. As shown, the flared trench openings 416 prevent trench overhang from becoming an issue during the copper seed deposition.

The second deposition process for filling the trench with copper is an electroplating process that deposits a bulk copper layer onto the copper seed layer (process 316). The copper seed layer functions as a catalyst for the copper electroplating process. The flared trench openings allow the bulk copper layer to fill the trench in a substantially void-free manner without issues such as trench overhang. In implementations of the invention, the bulk copper layer may have a low impurities content (e.g., less than 100 ppm) and an overburden thickness of greater than 0.2 micrometers (μm). Alternate deposition methods may be used to deposit the bulk copper layer, such as electroless plating, PVD, chemical vapor deposition (CVD), or atomic layer deposition (ALD).

FIG. 4H illustrates the trenches 414 after an electroplating deposition process has been carried out to deposit a bulk copper layer 424 onto the copper seed layer 422. The bulk copper metal 424 enters each trench 414 through its flared trench opening 416 where, due to the large width of the opening 416, issues such as trench overhang and pinching off of the trench opening are substantially eliminated. For instance, as shown in FIG. 4H, the bulk copper layer 424 completely fills the trench 414 in a substantially void-free manner.

After the trench is filled, the newly formed copper interconnect may undergo an optional annealing process (process 318). Annealing of the deposited copper metal allows large copper grains to be grown. This is particularly useful for sub-50 nm trenches because a large number of grain boundaries can have a significant detrimental impact on electrical resistance for copper interconnects this size. Growing larger copper grains reduces the number of grain boundaries, which in turn lowers the resistance of the copper interconnect. In implementations of the invention, the copper interconnect may be annealed at a temperature between around 100° C. and 400° C. for a time period between around 15 seconds and 5 minutes.

After the annealing process, the copper interconnect may undergo a chemical mechanical polishing (CMP) process to remove excess copper metal, barrier layer metal, and adhesion layer metal (process 320). The CMP process may also remove the flared trench opening, thereby completing the fabrication of a copper interconnect in accordance with implementations of the invention.

FIG. 4I illustrates the trenches 414 after a CMP process is used to planarize the structure and remove the flared trench openings 416. The CMP results in the formation of finalized copper interconnects 426. As shown, the copper interconnects 426 do not have any voids.

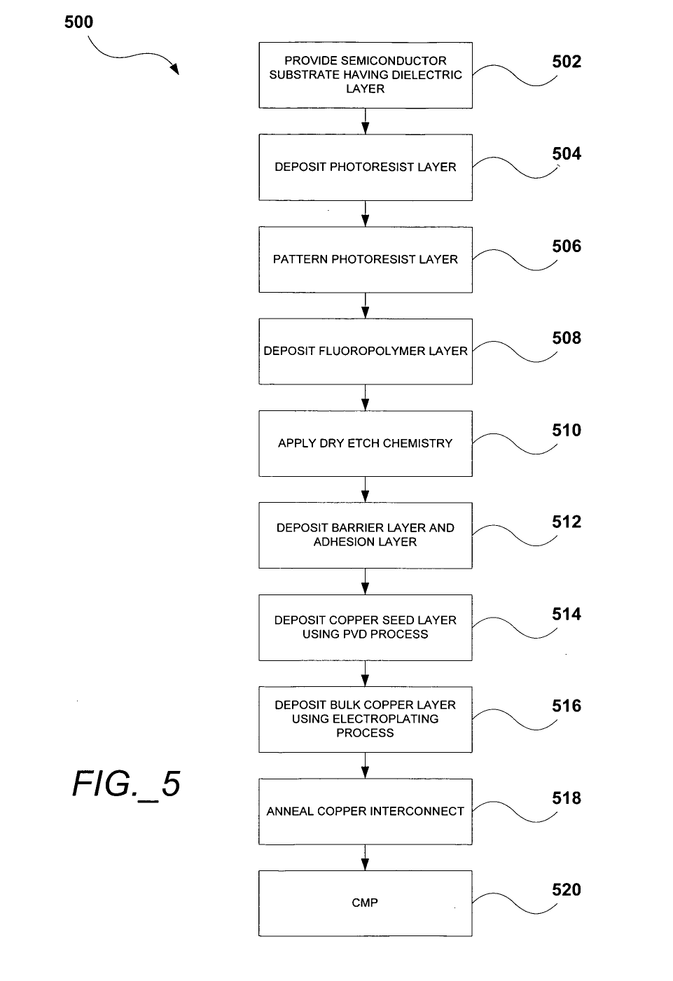

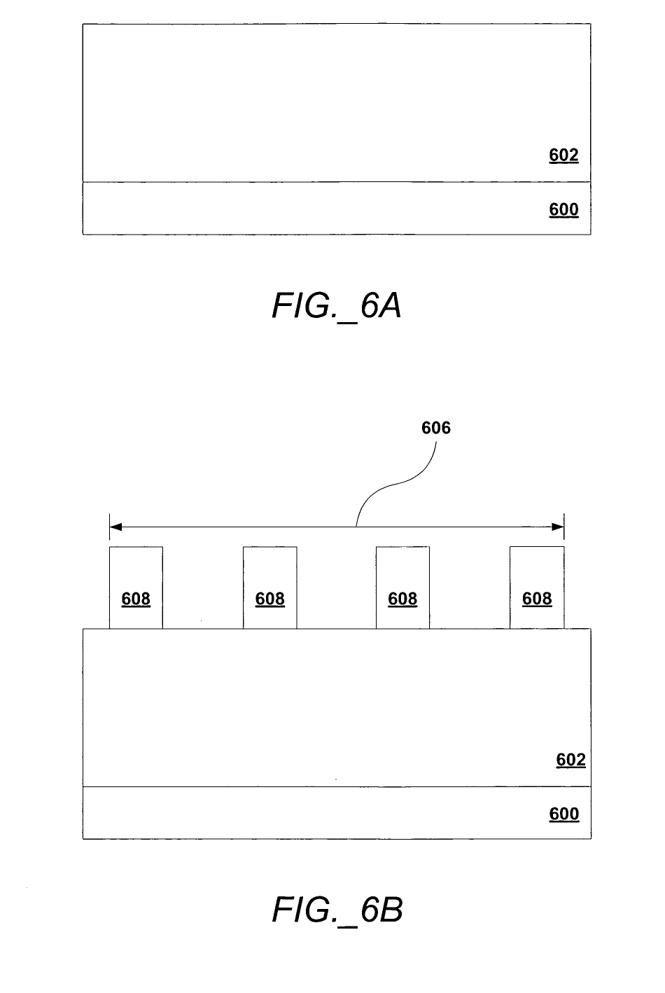

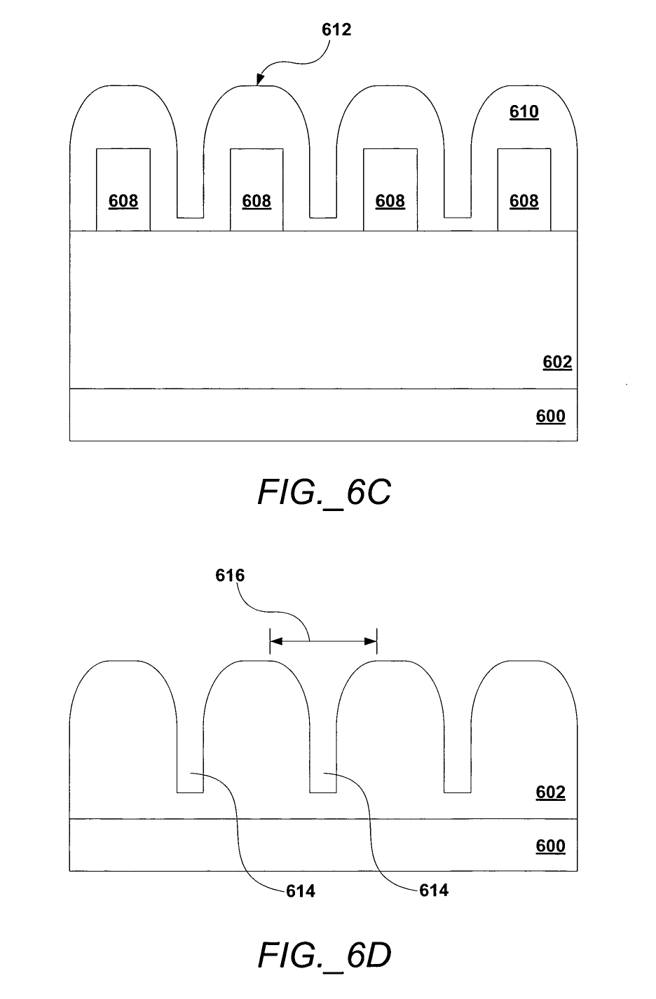

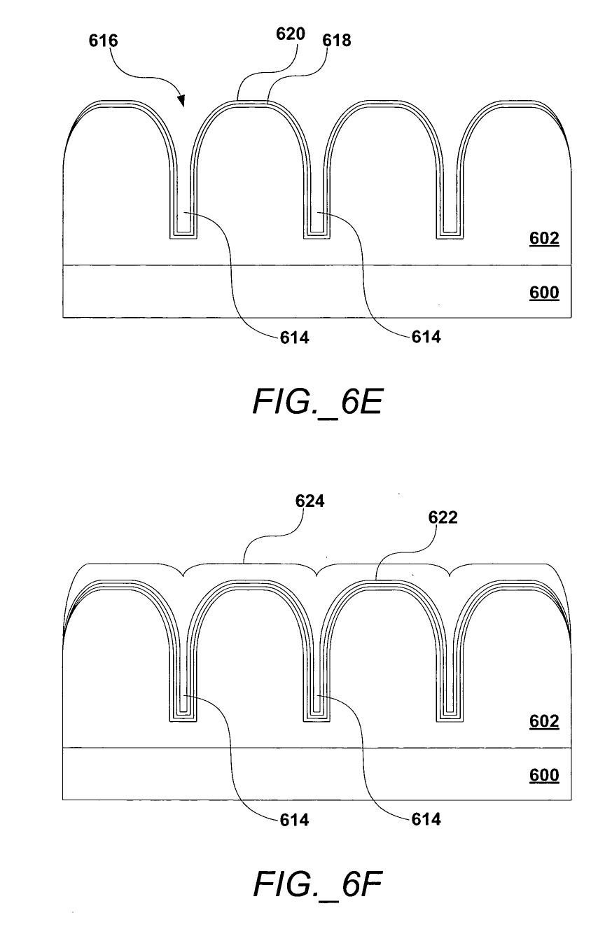

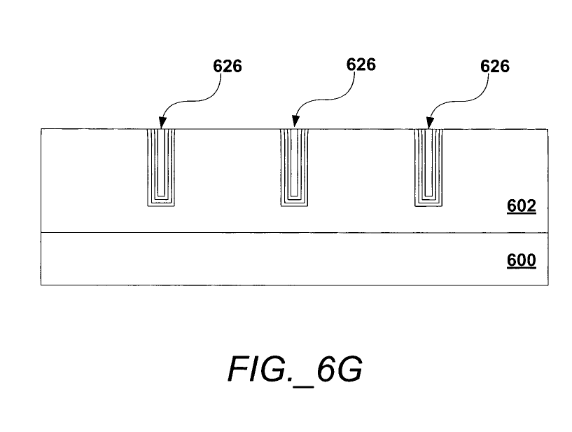

FIG. 5 is a damascene fabrication process 500 for forming a copper interconnect using a flared trench opening in accordance with another implementation of the invention. FIGS. 6A to 6G illustrate structures that are formed when carrying out the fabrication process 500. To aid in understanding this implementation, the FIGS. 6A to 6G will be referenced during the discussion of the fabrication process 500.

A semiconductor substrate is again provided that includes a dielectric layer (process 502 of FIG. 5). The semiconductor substrate may be formed using bulk silicon, a silicon-on-insulator substructure, or any other materials known in the art for use as a semiconductor substrate, including the materials described above. Active devices may be formed on the semiconductor substrate, including but not limited to CMOS transistors, contacts, isolation structures, and capacitors. FIG. 6A illustrates a semiconductor substrate 600 having a dielectric layer 602 deposited thereon that may include one or more vias that are not shown. As explained above, the vias may be present if the method of FIG. 5 is incorporated into,a dual damascene process for forming interconnects.

Next, a layer of photoresist material is deposited atop the dielectric layer (process 504) and patterned using conventional photolithography techniques to form a photoresist mask (process 506). FIG. 6B illustrates a photoresist mask 606 that is formed after a photoresist layer has been deposited and patterned. The photoresist mask 606 is composed of a plurality of individual photoresist structures 608 that shield portions of the dielectric layer 602. The exposed portions of the dielectric layer 602 that are vulnerable to an etching process.

In accordance with this implementation of the invention, a conformal fluoropolymer layer is then deposited over the photoresist structures using a plasma process (process 508). The process parameters for the fluoropolymer deposition are chosen such that the fluoropolymer layer forms rounded peaks over the photoresist structures. A pair of adjacent rounded peaks then defines an outwardly flared trench opening, similar to the etched photoresist structures shown in FIG. 4D.

In implementations of the invention, the plasma-deposited conformal layer of fluoropolymer may be deposited through either a single deposition step or a sequence of alternating deposition and etch-back steps. The deposition of the fluoropolymer may occur in a semiconductor grade dry-etch chamber at a pressure between around 20 and around 300 mTorr. A mixture of deposition gases may be used to deposit the fluoropolymer layer. This mixture of deposition gases may include one or more of CH₃F, CH₂F₂, CH₃F, CF₄, C₄F₆, C₄F₈, H₂, O₂, Ar, He, Xe, N₂, and CO. The deposition gases may be introduced at flow rates that range from 0-2000 standard cubic centimeters per minute (SCCM). As this is a plasma-deposition process, the RF power used during deposition may range from around 100 W to around 800 W. The RF power may be applied at a variety of frequencies and to either a top and/or a bottom electrode.

If an etch-back process is used, one or more etch-back gases may be applied to the deposited fluoropolymer layer to form rounded peaks. In implementations of the invention, a mixture of etch-back gases may be used that includes one or more of CF₄, CF₃H, C₄F₈, O₂, Ar, He, Xe, N₂, and CO. The flow rates for the etch-back gases may range from 0-2000 SCCM. The RF power applied during the etch-back process may range from around 100 W to around 2000 W and the RF power may be applied at a variety of frequencies and to either a top and/or a bottom electrode.

In various implementations of the invention, multiple cycles of a fluoropolymer deposition followed by an etch-back step may be used. In some implementations of the invention, up to 20 such cycles may be used. Alternately, the etch-back may be unnecessary and only the fluoropolymer deposition process may be used.

FIG. 6C illustrates a fluroropolymer layer 610 that has been deposited over the photoresist structures 608. As shown, the fluroropolymer material is deposited such that a flared trench profile is defined in the fluroropolymer layer 610. Peaks 612 in the fluroropolymer layer 610 have rounded edges defining outwardly flared trench openings that can be transferred to the underlying dielectric layer 602 during a subsequent etching process.

Next, a dry etch chemistry is applied to transfer the trench profile defined in the fluroropolymer layer into the underlying dielectric layer (process 510). As will be appreciated by those of skill in the art, conventional dry etch chemistries for etching the fluroropolymer layer and the dielectric material may be used, such as the plasma etching processes described above. The trenches formed in the dielectric layer therefore have flared trench openings in accordance with implementations of the invention. Following the dry etch, the wafer may be cleaned either by a plasma ashing process or a wet chemistry clean, as is known in the art, to remove any remaining fluoropolymer.

FIG. 6D illustrates trenches 614 that have been etched into the dielectric layer 602 using the fluroropolymer layer 610. The trenches 614 have flared trench openings 616, similar to the flared trench profile that was defined in the fluroropolymer layer 610.

Once the trenches have been formed with flared trench openings, metal may be deposited to form the interconnect structure. First, a barrier layer and an adhesion layer are deposited into the trenches using a sputtering process (process 512). The barrier layer and adhesion layer may be formed using the barrier/adhesion metals mentioned above. FIG. 6E illustrates the trenches 614 after a barrier layer 618 and an adhesion layer 620 have been deposited. As shown, the flared trench openings 616 remain wide open for the subsequent copper deposition.

After the barrier and adhesion layers are formed, two separate deposition processes are used to fill the trench with copper metal. The first deposition process is a PVD process that forms a non-conformal copper seed layer (process 514). The second deposition process is an electroplating process that deposits a bulk copper layer onto the copper seed layer (process 516). The flared trench openings prevent trench overhang from occurring during the copper deposition, therefore, neither the copper seed layer nor the bulk copper layer pinch off the trenches. The flared trench openings therefore allow the copper layer to fill the trench in a substantially void-free manner. In implementations of the invention, the bulk copper layer may have a low impurities content (e.g., less than 100 ppm) and an overburden thickness of greater than 0.2 micrometers (μm).

FIG. 6F illustrates the trenches 614 after a conventional copper seed layer 622 and a bulk copper layer 624 have been deposited onto the adhesion layer 620. Due to the large width of the flared trench openings 616, issues such as trench overhang and pinching off of the trench opening are substantially eliminated, and the bulk copper layer 624 completely fills the trench 614 in a substantially void-free manner.

After the trench is filled, the newly formed copper interconnect may undergo an optional annealing process (process 518). As explained above, annealing of the deposited copper metal allows larger copper grains to be grown that lowers the resistance of the copper interconnect. In implementations of the invention, the copper interconnect may be annealed at a temperature between around 100° C. and 400° C. for a time period between around 15 seconds and 5 minutes.

After the annealing process, the copper interconnect may undergo a CMP process to remove excess copper metal, barrier layer metal, and adhesion layer metal (process 520). The CMP process may also remove the flared trench opening, thereby completing the fabrication of a copper interconnect in accordance with implementations of the invention. FIG. 6G illustrates the trenches 614 after a CMP process is used to planarize the structure and remove the flared trench openings 616, forming finalized copper interconnects 626.

In further implementations of the invention, materials other than fluoropolymers may be deposited over photoresist structures to define a flared trench profile. In some implementations, a sacrificial light-absorbing material (SLAM) may be used in lieu of a fluoropolymer. Examples of SLAMs that may be used include, but are not limited to, conventional spin-on glass materials that are well known in the art. In some instances, the etching of the SLAM layer may be modified to define the flared trench profile required for implementations of the invention.

In yet another implementation of the invention, a trench profile may be defined in which the trenches are interconnected at their openings. In some implementations, this interconnected trench profile may be defined in a material layer (e.g., the fluoropolymer layer or the SLAM layer) and then transferred into the underlying dielectric layer during a subsequent etching process. In other implementations, conventional or flared trenches may be defined in the dielectric layer and an etching process may be used to interconnect the trenches. Then, after the metals are deposited and the copper interconnects are formed, a CMP process may be used to remove the interconnected top portion of the trenches to isolate the trenches and form individual copper interconnects.

Accordingly, methods have been provided for forming trenches with flared trench openings that may be used in a damascene process to form copper interconnects. The use of flared trench openings substantially reduces or eliminates the occurrence of trench overhang that can lead to voids within the copper interconnects. The methods provided herein therefore enable void-free filling of sub-50 nm interconnect features using PVD copper seed layers and electroplated bulk copper layers. This extends the use of PVD and electroplating to the sub-50 nm level.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
providing a semiconductor substrate having a dielectric layer deposited thereon;
depositing a photoresist layer atop the dielectric layer;
patterning the photoresist layer to form at least two photoresist structures;
applying a plasma etch to define a flared trench profile in the photoresist structures;
applying a dry etch chemistry to etch a trench in the dielectric layer using the photoresist structures as a mask, wherein the flared trench profile is transferred to the dielectric layer;
depositing a barrier metal layer into the trench;
depositing an adhesion metal layer into the trench;
depositing a copper metal seed layer into the trench;
depositing a bulk copper metal layer into the trench; and
polishing the trench to remove excess metal and the flared opening.

2. The method of claim 1, wherein the dielectric layer comprises SiO₂, CDO, PFCB, or FSG.

3. The method of claim 1, wherein the photoresist layer is deposited using a SOD process.

4. The method of claim 1, wherein patterning the photoresist mask comprises:
exposing the photoresist layer to ultraviolet radiation through an optical mask, wherein the mask defines the at least two photoresist structures;
baking the photoresist layer; and
developing the photoresist layer to form the at least two photoresist structures.

5. The method of claim 1, wherein the plasma etch comprises at least one of Ar, forming gas, P, N, C, or B.

6. The method of claim 5, wherein process parameters for the applying of the plasma etch comprise an RF energy between 300 W and 1200 W applied at a frequency of 13.56 MHz, 27 Mhz, or 60 MHz, and a reactor pressure between around 150 mTorr and around 500 mTorr.

7. The method of claim 1, wherein the dry etch chemistry comprises an anisotropic second plasma etch, and wherein the second plasma comprises at least one of CF₄, CF₃H, CF₂H₂, C₄F₈, C₄F₆, O₂, Ar, He, Xe, N₂, and CO.

8. The method of claim 7, wherein process parameters for the applying of the second plasma etch comprise a gas flow between 2 SCCM and 1000 SCCM, a reactor pressure between around 20 mTorr and around 100 mTorr, and an RF energy between 500 W and 4500 W applied at a frequency of 2 MHz, 13.56 MHz, 27 MHz, or 60 MHz.

9. The method of claim 1, wherein the barrier metal layer comprises at least one of TaN, WN, TiN, MoN, or NbN and wherein the adhesion metal layer comprises at least one of Ta, Ru, Ti, W, Mo, Nb, or Ir.

10. The method of claim 1, wherein the depositing of the barrier metal layer comprises using a PVD process to deposit the barrier metal layer and wherein the depositing of the adhesion metal layer comprises using a PVD process to deposit the adhesion metal layer.

11. The method of claim 1, wherein the depositing of the copper metal seed layer comprises using a PVD process to deposit the copper metal seed layer.

12. The method of claim 1, wherein the depositing of the bulk copper metal layer comprises using an electroplating process to deposit the bulk copper metal layer.

13. The method of claim 1, further comprising annealing the deposited copper metal.

14. The method of claim 13, wherein the copper metal is annealed at a temperature between around 100° C. and 400° C. for a time period between around 15 seconds and 5 minutes.

15. A method comprising:
providing a semiconductor substrate having a dielectric layer deposited thereon;
depositing a photoresist layer atop the dielectric layer;
patterning the photoresist layer to form at least two photoresist structures;
depositing a fluoropolymer layer atop the photoresist structures in such a manner that the fluoropolymer layer includes rounded peaks located above the photoresist structures; and
applying a dry etch chemistry to etch a trench in the dielectric layer, wherein the fluoropolymer layer functions as a mask that imparts a flared opening to the trench.

16. The method of claim 15, wherein the fluoropolymer is deposited using a plasma deposition process.

17. The method of claim 16, wherein a mixture of deposition gases used to deposit the fluoropolymer include one or more of CH₃F, CH₂F₂, CH₃F, CF₄, C₄F₆, C₄F₈, H₂, O₂, Ar, He, Xe, N₂, and CO.

18. The method of claim 17, wherein process parameters for the plasma deposition process comprise a reactor pressure between around 20 mTorr and 300 mTorr, deposition gas flow rates up to 2000 SCCM, and an RF power between around 100 W and around 800 W.

19. The method of claim 18, wherein the fluoropolymer is deposited using a sequence of alternating deposition and etch-back processes.

20. The method of claim 19, wherein the etch-back process uses one or more etch-back gases to modify the fluoropolymer, and wherein the etch-back gases include one or more of CF₄, CF₃H, C₄F₈, O₂, Ar, He, Xe, N₂, and CO.

21. The method of claim 20, wherein process parameters for the etch-back process comprise deposition gas flow rates up to 2000 SCCM and an RF power between around 100 W and around 2000 W.

22. The method of claim 19, wherein up to 20 cycles of alternating deposition and etch-back processes may be used.

23. The method of claim 15, wherein the dry etch chemistry comprises an anisotropic plasma etch, and wherein the plasma comprises at least one of CF₄, CF₃H, CF₂H₂, C₄F₈, C₄F₆, O₂, Ar, He, Xe, N₂, and CO.

24. The method of claim 23, wherein process parameters for the anisotropic plasma etch comprise a gas flow between 2 SCCM and 1000 SCCM, a reactor pressure between around 20 mTorr and around 100 mTorr, and an RF energy between 500 W and 4500 W applied at a frequency of 2 MHz, 13.56 MHz, 27 MHz, or 60 MHz.

25. The method of claim 15, further comprising:
depositing a barrier metal layer into the trench;
depositing an adhesion metal layer into the trench;
depositing a copper metal seed layer into the trench;
depositing a bulk copper metal layer into the trench; and
polishing the trench to remove excess metal and the flared opening.

26. The method of claim 25, wherein the barrier metal layer comprises at least one of TaN, WN, TiN, MoN, or NbN and wherein the adhesion metal layer comprises at least one of Ta, Ru, Ti, W, Mo, Nb, or Ir.

27. The method of claim 25, wherein the depositing of the barrier metal layer comprises using a PVD process to deposit the barrier metal layer and wherein the depositing of the adhesion metal layer comprises using a PVD process to deposit the adhesion metal layer.

28. The method of claim 25, wherein the depositing of the copper metal seed layer comprises using a PVD process to deposit the copper metal seed layer.

29. The method of claim 25, wherein the depositing of the bulk copper metal layer comprises using an electroplating process to deposit the bulk copper metal layer.

30. A method comprising:
providing a semiconductor substrate having a dielectric layer deposited thereon;
depositing a photoresist layer atop the dielectric layer;
patterning the photoresist layer to form at least two photoresist structures;
depositing a SLAM layer atop the photoresist structures, wherein the SLAM layer includes rounded peaks located over the photoresist structures; and
applying a dry etch chemistry to etch a trench into the dielectric layer, wherein the SLAM layer functions as a mask that causes the trench to have a flared opening.

31. The method of claim 30, wherein the SLAM layer comprises a spin-on glass material.

32. The method of claim 30, wherein the dry etch chemistry comprises an anisotropic plasma etch.

33. A method comprising:
providing a semiconductor substrate having a dielectric layer deposited thereon;
depositing and patterning a photoresist layer atop the dielectric layer to form at least two photoresist structures;
applying a first plasma to round-off the top edges of the photoresist structures; and
applying a second plasma to etch a trench in the dielectric layer, wherein the rounded-off top edges impart a flared opening to the trench.

34. The method of claim 33, wherein the first plasma comprises at least one of Ar, forming gas, P, N, C, or B.

35. The method of claim 34, wherein process parameters for the applying of the first plasma comprise an RF energy between 300 W and 1200 W applied at a frequency of 13.56 MHz, 27 Mhz, or 60 MHz, and a reactor pressure between around 150 mTorr and around 500 mTorr.

36. The method of claim 33, wherein the second plasma comprises at least one of CF₄, CF₃H, CF₂H₂, C₄F₈, C₄F₆, O₂, Ar, He, Xe, N₂, and CO.

37. The method of claim 36, wherein process parameters for the applying of the second plasma comprise a gas flow between 2 SCCM and 1000 SCCM, a reactor pressure between around 20 mTorr and around 100 mTorr, and an RF energy between 500 W and 4500 W applied at a frequency of 2 MHz, 13.56 MHz, 27 MHz, or 60 MHz.
